(19) United States
(12) Patent Application Publication
(10) Pub. No.: US 2009/0219496 A1
(43) Pub. Date: Sep. 3, 2009

(54) Methods of Double Patterning, Photo Sensitive Layer Stack for Double Patterning and System for Double Patterning

(76) Inventors: Frank-Michael Kamm, Dresden (DE); Christoph Noelscher, Nuernberg (DE); Stephan Wege, Dresden (DE); Rolf Weis, Dresden (DE)

Correspondence Address: SLATER & MATSIL, L.L.P., 17950 PRESTON ROAD, SUITE 1000, DALLAS, TX, 75252, US

(21) Appl. No.: 12/040,389

(22) Filed: Feb. 29, 2008

(51) Int. Cl. G03B 27/42; G03F 7/004; G03F 7/00

(52) U.S. Cl. 355/53; 430/322; 430/270.1

(57) ABSTRACT

Double patterning a photo sensitive layer stack, is disclosed including providing a substrate being coated with a first and a second photo resist layer, exposing both photo resist layers by employing lithographic projection steps, wherein a second lithographic projection step illuminates a latent image with a focal depth at least partially covering the second photo resist layer.

### TECHNICAL FIELD

Embodiments of the invention relate to methods of double patterning, photo sensitive layer stack for double patterning and system for double patterning.

### BACKGROUND

In recent developed techniques for lithographic techniques, patterning of a substrate is performed using double patterning. Double patterning is especially useful when printing a regular dense pattern on the substrate. In order to create sublithographic patterns, a pattern decomposition technique is employed, where a given pattern of dense minimum resolution structural elements is decomposited into two individual patterns.

Typically a lithographic projection apparatus is characterized by its minimum resolution which indicates the smallest possible line width which can be printed on a substrate. Theoretically, the minimum line width is given by the numerical aperture of the projection apparatus, the wavelength of its light source and a technology dependent factor k₁ which addresses mask and exposure technology dependent influences.

Double patterning can be performed by processing both decomposited patterns subsequently. It should be noted, that double patterning is a technique different to double exposure, where the photo resist is the same without processing between the two exposures.

Double patterning by line shrink or space shrink up-to-now needs at least an etch of a hardmask between the two imaging processes. Furthermore, a line-by-spacer-fill process needs a complex integration scheme. This has the disadvantage of high cost, and in the case of double-line-shrink or double-space-shrink an unloading from the scanner, etch, clean and then a new loading on the scanner/track system for second patterning. A deformation of the wafer may occur during etch which has deteriorating impact on overlay. Accordingly, there is a need in the art to overcome the above identified problems.

### BRIEF DESCRIPTION OF THE DRAWINGS

In the accompanying drawings:

FIG. 1 illustrates an optical projection system;

FIGS. 2A to 2G each illustrate a photo sensitive layer stack in a cross-sectional side view at various stages of processing;

FIGS. 3A to 3E each illustrate a photo sensitive layer stack in a cross-sectional side view at various stages of processing;

FIG. 4 illustrates a photo sensitive layer stack in a cross-sectional side view;

FIGS. 5A to 5C each illustrate a photo sensitive layer stack in a cross-sectional side view at various stages of processing;

FIGS. 6A to 6C each illustrate a photo sensitive layer stack in a cross-sectional side view at various stages of processing;

FIG. 7 illustrates a flow diagram of process steps;

FIG. 8 illustrates a flow diagram of process steps;

FIG. 9 illustrates a flow diagram of process steps; and

FIG. 10 illustrates a flow diagram of process steps.

### DETAILED DESCRIPTION OF ILLUSTRATIVE EMBODIMENTS

Embodiments of methods and systems of double patterning are discussed in detail below. It is appreciated, however, that the present invention provides many applicable inventive concepts that can be embodied in a wide variety of specific contexts. The specific embodiments discussed are merely illustrative of specific ways and do not limit the scope of the invention.

In the following, embodiments and/or implementations of the method and the system are described with respect to improving resolution capabilities during lithographic projection of a layer of an integrated circuit. The embodiments, however, might also be useful in other respects, e.g., improvements in process capabilities, improvements in printing parts of a layout of a pattern together with further patterning steps, yield enhancement techniques or the like.

Furthermore, it should be noted that the embodiments and/or implementations are described with respect to dense line-space-patterns but might also be useful in other respects including but not limited to dense patterns, semi dense patterns or patterns with isolated lines, as well as for contacts and combinations between all them. Lithographic projection can also be applied during manufacturing of different products, e.g. semiconductor circuits, thin film elements. Other products, e.g., liquid crystal panels or the like might be produced as well.

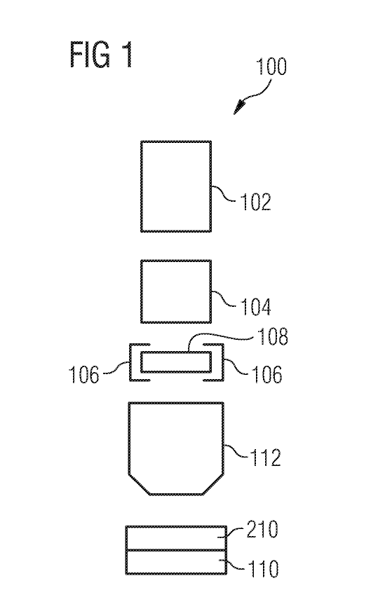

With respect to FIG. 1, a set-up of a lithographic projection apparatus 100 is shown in a side view. It should be appreciated that FIG. 1 merely serves as an illustration, i.e., the individual components shown in FIG. 1 neither describe the full functionality of a lithographic projection apparatus 100 nor are the elements shown true scale. Furthermore, the described embodiment uses a projective optical system in the UV range employing a certain demagnification. However, other lithographic system including proximity projection, reflective projection or the like employing various wavelengths from the visible to ultraviolet to extreme ultraviolet range can be employed. Within the described embodiments, a projective optical system using a UV light source of 193 nm is employed having a certain demagnification. However, other wavelengths like 248 nm or 157 nm are not excluded.

In FIG. 1 a photolithographic projection apparatus is schematically shown in a side view. Lithographic projection apparatus 100 includes a light source 102, an illumination optic 104 and a mask holder 106 suitable to hold a photomask 108. Light coming from light source 102 which is, e.g., an Excimer laser with 193 nm wavelength, impinges on photomask 108 through illumination optic 104. This part of the light which is not shielded or attenuated on photomask 108 is further projected onto a substrate 110 through projection optics 112. A photo sensitive layer stack 210 is deposited on the substrate 110. Wafer and reticle may be scanned simultaneously, and also an immersion liquid may be used between lens and wafer.

The term “substrate” includes semiconductor wafers having an already structured layer or already structured layer systems being arranged partially or fully covering the substrate. Silicon, Germanium or Gallium arsenide either doped or undoped are suitable materials. However, other materials of semiconductor wafers are not excluded. Furthermore other substrates like glass, plastic or the like are also within the scope of term “substrate”.

The photo mask 108 comprises a mask pattern, i.e., being composed of light absorptive or light attenuating elements. Light absorptive elements can be provided by, e.g., Chrome patterns. Light attenuating elements can be provided by, e.g., Molybdenum-silicium elements. The mask pattern is derived from a layout pattern which can be provided by a computer aided design system, in which structural elements of the layout pattern are generated and stored.

A lithographic projection apparatus 100 is characterized by its minimum resolution which indicates the smallest possible line width which can be printed on substrate 110. Theoretically, the minimum line width is given by the numerical aperture of projection apparatus 100, the wavelength of light source 102 and the technology dependent factor k₁ which addresses mask and exposure technology dependent influences.

According to an embodiment, the patterning of substrate 110 is performed using double patterning. Double patterning is especially useful when printing a regular dense pattern on the substrate. In order to create sublithographic patterns, a pattern decomposition technique is employed, where a given pattern of dense minimum resolution structural elements is decomposited into two individual patterns.

Double patterning can be performed by processing both decomposited patterns subsequently. It should be noted, that double patterning is a technique different to double exposure, where the photo resist is the same without processing between the two exposures. When using double patterning, the pattern width that is obtained in the lithographic process is pushed below the limit of optical imaging, i.e., P=(2·k₁·λ)/NA, where P is the pattern width or feature size, k₁ a process specific constant, X the wavelength of the radiation source and NA the numerical aperture of a lithographic projection apparatus used. A pitch fragmentation below k1=0.25 can be achieved by double patterning.

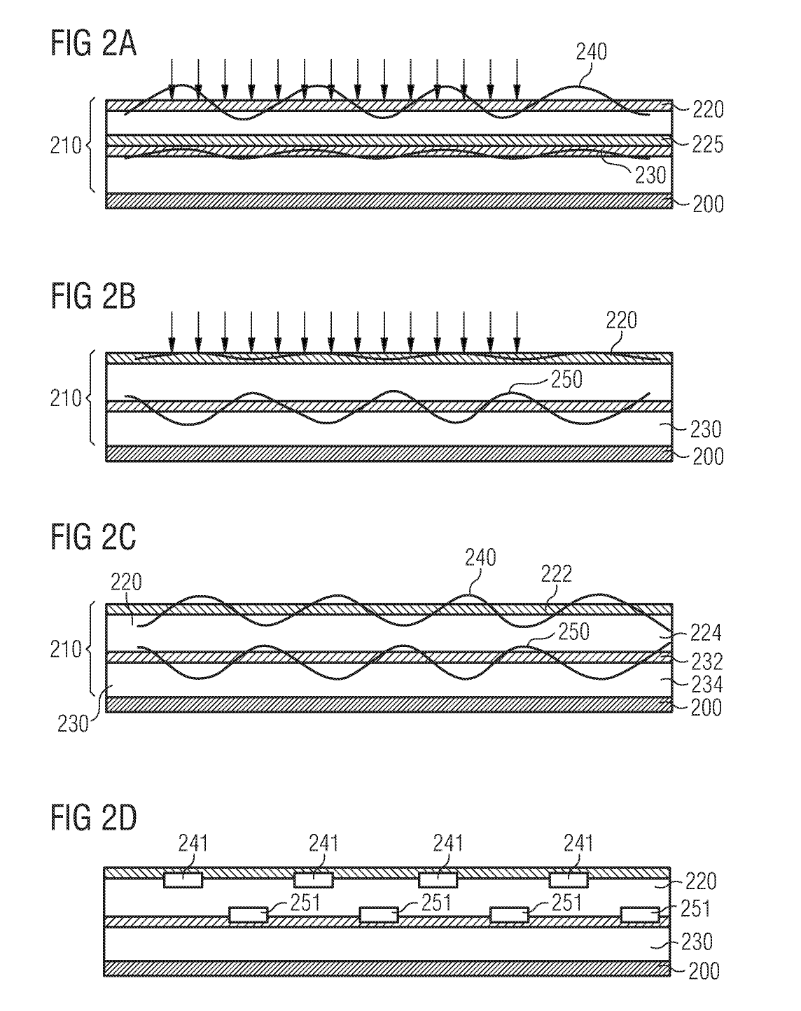

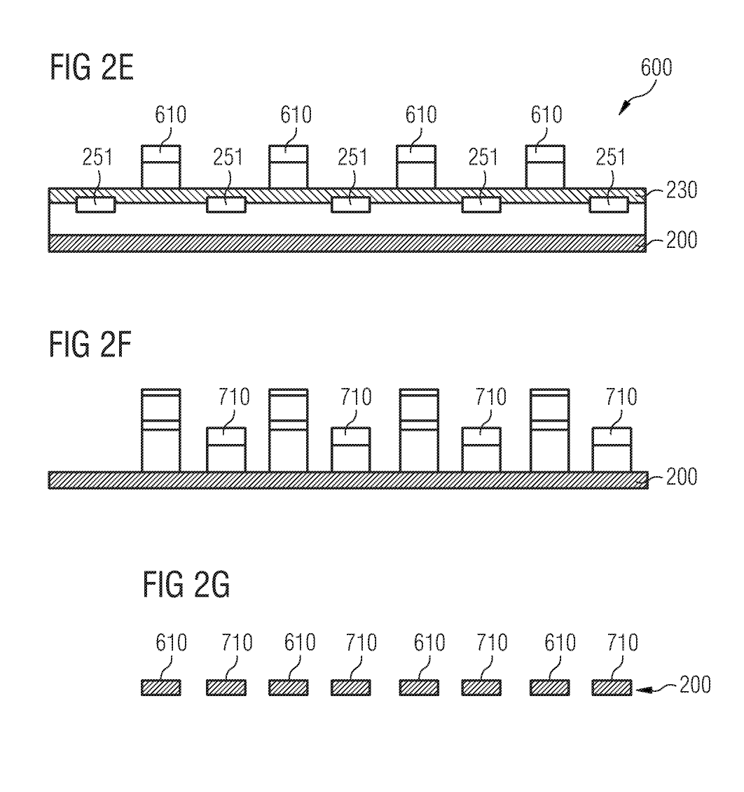

An embodiment of the invention is now further described making reference to FIGS. 2A to 2G.

FIG. 2A shows a substrate being coated with two photosensitive layers. On substrate 110 a layer 200 is shown, which is subject of being patterned in a double patterning process. Above this layer, a photosensitive layer stack 210 is arranged. The photosensitive layer stack 210 includes a first photo resist layer 220 and a second photo resist layer 230. In between can be a polymer 225, either photosensitive or not.

During a first exposure step, photolithographic apparatus 100 is tuned such, that its focal depth covers the first photo resist layer 220. Schematically, this is indicated by a latent image 240, which shows an intensity distribution of light during projection of the first pattern. Focal depth in this respect means a vertical range with respect to the surface plane of the substrate in which a clearly defined image is projected.

In an implementation, an average intensity dose with low contrast, i.e., only a blur or diffuse image, is applied to photo resist layer 230 as the focal depth is not large enough to provide a clearly defined image within photo resist layer 230, and the distance of layer 220 and 230 is chosen to avoid contrast inversion so that no photolithographic printing of a pattern occurs. For exposing the second pattern, the focus of lithographic projection apparatus 100 is shifted towards the second photo resist layer 230.

The second exposing step is schematically shown in FIG. 2B. There a second latent image 250 is shown which is formed within second photo resist layer 230. In contrast to FIG. 2B, first photo resist layer 220 is now out of focus so that only an average dose illuminates the first photo resist layer 220 so that no photolithographic printing of a pattern occurs, and the second exposure produces some intensity maxima between maxima from the first patterns, e.g., by using the same mask as for the first exposure but displaced by, e.g., half of the densest pitch.

The latent images of the double exposure are shown in FIG. 2C. FIG. 2C shows the photosensitive layer stack 210 with the first photo resist layer 220 and the second photo resist layer 230 above the substrate layer 200. As can be seen from the two latent images 240 and 250, both photo resist layers are exposed twice so as to expose a first pattern in the first photo resist layer 220 and a second pattern in the second photo resist layer 230.

It should be noted that the averaged doses which are applied during the out-of-focus illumination reduces the contrast of the resulting images which, however, can be attributed by employing a high contrast exposure step. This can be achieved, for example, by adjusting a mask bias and the imaging conditions, e.g., by a three-beam-interference so as to have a high image contrast and in turn reducing the depth of focus during exposure from approximately 600 nm to about 100 to 150 nm.

As can be seen from FIGS. 2A to 2C, the resulting first and second latent images can be achieved for either a positive or a negative resist system. It should be noted, however, that the first photo resist layer 220 and the second photo resist layer 230 have the same sensitivity type.

Accordingly, the first and second photo resist layer are either both positive or both negative resist systems. The resist type selected for the first photo resist layer should be sufficiently transparent in order to allow suitable exposure of the second photo resist layer 230. The same holds for the material between both layers which is chosen to be rather transparent.

It should be noted that between the two exposure steps no processing like bake, chemical treatment or development step of the first photo resist layer has been performed. Accordingly, the substrate may remain within the photolithographic projection apparatus 100 between the two exposing steps which greatly reduces overlay and alignment errors, beside the inherent process simplicity.

The development steps of the photosensitive layer stack which has been exposed as shown in FIG. 2C are now further described making reference to FIGS. 2D to 2G.

In this implementation, the second photo resist layer 230 is provided as a so-called top-surface imaging dry developable resist. This type of resist has mainly a small reaction depth with a gaseous or liquid agent which is applied at the surface and diffuses either in exposed or in unexposed region, depending on system. By insertion of, e.g., Si, Ge or Ti the diffused and reacted region becomes etch resistant in a dry etch, e.g., with anisotropic reactive ion etching, e.g., with oxygen ions. The potential reaction layer sheet is herein after referred to by reference numeral 232 above an intermediate layer 234. The first photo resist layer 220 can also be composed as a top-surface imaging dry developer resist having a first photosensitive region 222 and a first intermediate layer 224.

It should be noted, however, that other combinations of resist types can also be employed. FIG. 2D shows a cross-section through the photosensitive layer stack after a post-exposure baking. After a post-exposure bake the first photosensitive layer 222 is further stabilized by performing a so-called silylation step. Silylation comprises an incorporation of silicon into the photosensitive layer. This ensures that the etch resistance of the exposed photosensitive layer is enlarged.

Silylation of the first photosensitive layer can be performed either by applying a specific gas or a liquid. It is also possible to apply a top coat layer (not shown in FIG. 2D) in order to achieve silylation. The second photosensitive layer 232 is made etch resistant by diffusion of an agent from the intermediate layer. The irradiated areas after both exposure steps are referred to by reference numeral 241 and 251, respectively.

FIG. 2E shows a cross-section through photosensitive layer stack 210 after developing the first photo resist layer 220. The first pattern 600 with structural elements 610 is formed by performing either a wet development of an silicon containing resist further performing an underlayer etch or by silylation of the top surface using a gas or a liquid with subsequent dry development, as described above.

A further contrast enhancement of the structural elements 610 can be achieved by a plasma operation step, which is performed so as to fully remove the first photo resist 220 from the uncovered areas between structural elements 610. This technique is known in the art as descum and can be performed on silylated areas.

Now making reference to FIG. 2F, development of second photo resist layer 230 is shown. It should be noted that silylation of the second photo resist layer 230 can be performed either before or after development of the first photo resist layer 220. When silylation is applied before development of the first photo resist layer, diffusion or reaction with the intermediate layers 234 and 224 can be employed, as described above, with enrichment of etch resistance providing species in the exposed or unexposed areas.

It is also possible to apply silylation after development of the first photo resist layer by a reaction with a suitable reactive environment, example given by applying a wet or gaseous chemistry. Afterwards a dry development of the second photo resist layer 230. This results in the second pattern 700 with structural elements 710. It should be noted that a descum step can also be applied after development of the second photo resist layer in order to remove intermediate layers.

Making reference now to FIG. 2G, the transfer of the remaining first and second structural elements 610 and 710 into the underlying substrate layer 200 is shown. This step is performed by an etching chemistry followed by an optional resist removal, for example. It should be noted, however, that processing can continue in many different ways which are known to a person skilled in the art. For example, the resulting structure can be used for structuring an underlying layer in the substrate or as mask for an implantation step or for any other process sequence for further processing the substrate.

The embodiment described with respect to FIGS. 2A to 2G uses a photosensitive layer stack with two different photo resist layers having the same sensitivity type. As no development step is performed after exposure of the first photo resist layer, the substrate may remain within the photolithographic projection apparatus 100 between the two exposure steps which greatly reduces overlay errors and errors induced by a substrate holder. Consequently, additional alignment or adjustment steps for the substrate may be avoided. It should be mentioned that mask alignment in mask holder 106 necessary for exchanging between first and second pattern can be performed with a much higher accuracy as compared to a wafer stage alignment in a substrate holder.

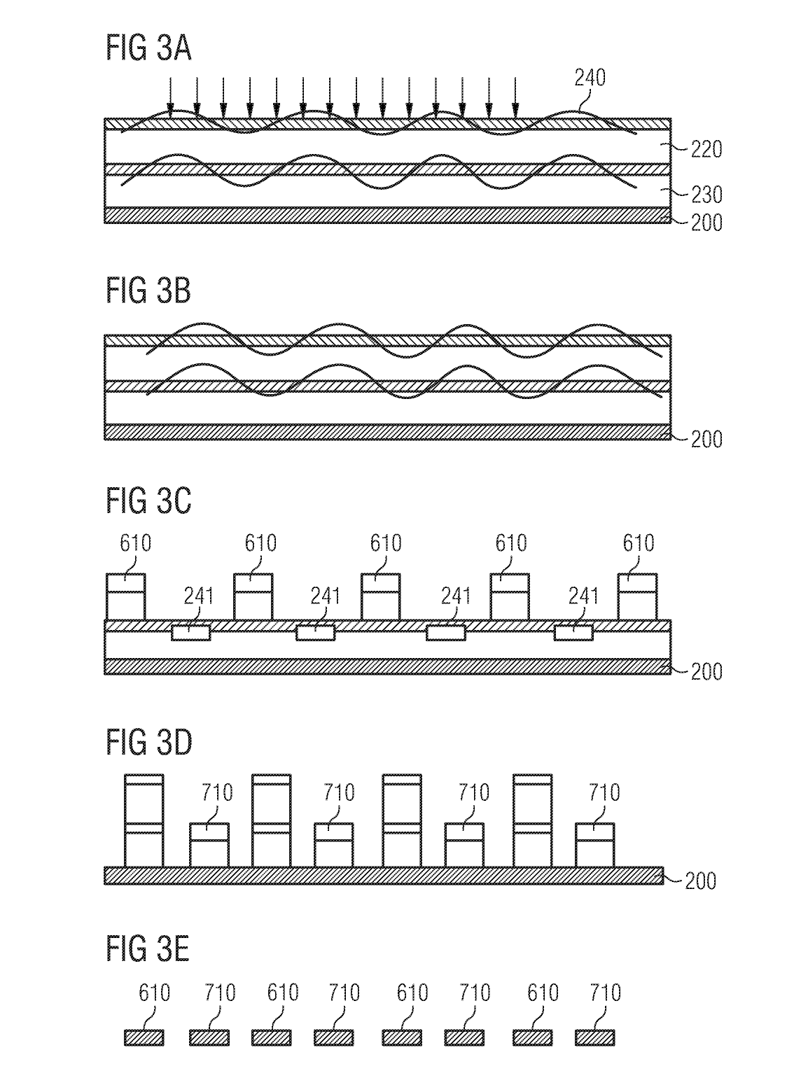

Making reference now to FIG. 3A, a photosensitive layer stack is shown which employs a two-layer system with opposite sensitivity types. In other words, the first photo resist layer 220 can be negative and the second photo resist layer 230 can be a positive type resist. Alternatively, the first photo resist layer can be positive and the second photo resist layer can be negative.

As a consequence, the second exposure can be avoided altogether if the focal depth of the photolithographic projection apparatus is selected to be enough around the isofocal point. In order to further facilitate this, thicknesses of first and second photo resist should be low. Furthermore, it should be noted that the pattern which is to be printed on the substrate can be decomposited in a way that only one exposure step is necessary.

As shown in FIG. 3B, the latent image 240 is provided by lithographic projection apparatus with a sufficiently larger depth of focus so as to expose both the first photo resist layer 220 and the second photo resist layer 230. The distance between layer 222 and 232 may be lowered. The depth of focus may be enlarged by two beam interference and/or focus drilling, e.g., by a tilted wafer stage during scanning.

Further processing continues by applying a post exposure bake, as shown in FIG. 3C. In this embodiment the second photo resist layer 230 is provided as a so-called top-surface imaging dry developable resist. The first photo resist layer 220 can also be composed as a top-surface imaging dry developable resist having a first photosensitive region 222 and a first intermediate layer 224 as shown with respect to FIG. 2. It should be noted, however, that other combinations of resist types can also be employed, e.g., first photosensitive region 222 can be a wet developable Si-containing positive resist.

FIG. 3C shows a cross-section through the photosensitive layer stack after post-exposure baking and after developing the first photo resist layer 220. After a post-exposure bake the first photosensitive layer 222 is further stabilized by performing a so-called silylation step. Silylation comprises an incorporation of silicon into the photosensitive layer. This ensures that etch properties of the photosensitive layer are changed for the following dry development steps. Silylation of the first photosensitive layer can be performed either by applying a specific gas or a liquid. It is also possible to apply a top coat layer (not shown in FIG. 3C) in order to achieve silylation. Furthermore, diffusion from the intermediate layer 224 can occur which achieves at least some silylation.

As a result, the first pattern 600 with structural elements 610 is formed by performing either a wet development of an, example given, silicon containing resist further performing an underlayer etch or by silylation of the top surface using a gas or a liquid with subsequent dry development, as described above.

A further contrast enhancement of the structural elements 610 can be achieved by a plasma operation step, which is performed so as to remove the first photo resist 220 from the uncovered areas between structural elements 610. This technique is known in the art as descum and can be performed on silylated areas.

Now making reference to FIG. 3D, development of second photo resist layer 230 is shown. It should be noted that silylation of the second photo resist layer 220 can be performed either before or after development of the first photo resist layer 220. In case silylation is applied before development of the first photo resist layer, diffusion or reaction with the intermediate layers 234 and 224 can be employed, as described above.

It is also possible to apply silylation after development of the first photo resist layer by a reaction with a suitable reactive environment, example given by applying a wet or gaseous chemistry. Afterwards a dry development of the second photo resist layer 230. This results in the second pattern 700 with structural elements 710. It should be noted that a descum step can also be applied after development of the second photo resist layer in order to remove intermediate layers. Furthermore, it is possible to employ cross-linking before development of second photo resist layer 230.

Making reference now to FIG. 3E, the transfer of the remaining first and second structural elements 610 and 710 into the underlying substrate layer 200 is shown, as already explained in connection to FIG. 2G.

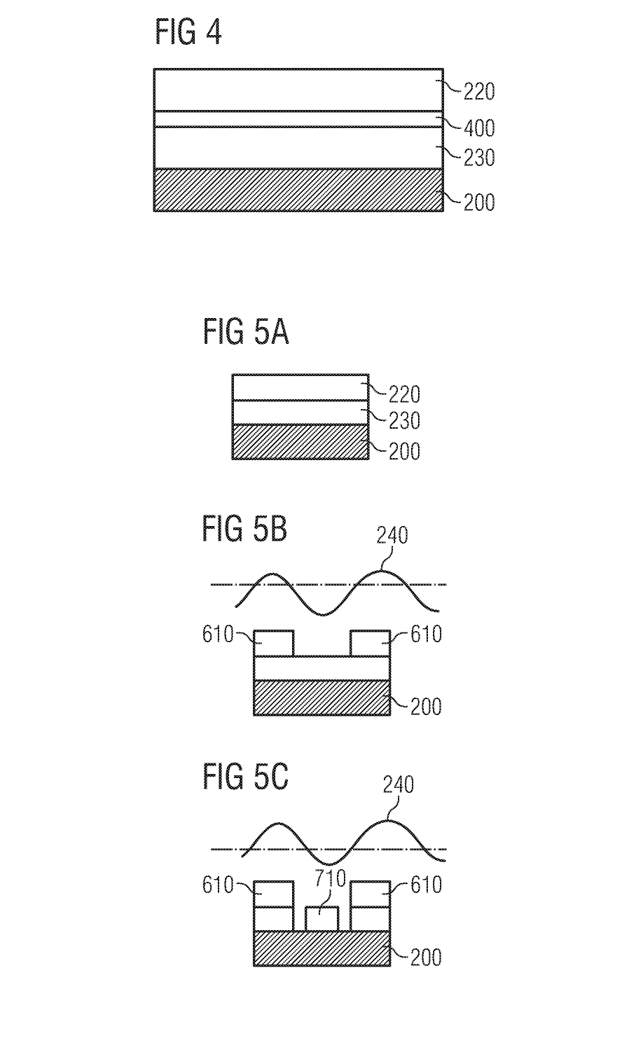

In FIG. 4, a further embodiment is shown. The embodiment described with respect to FIG. 3 uses a photosensitive layer stack with two different photo resist layers 220 and 230 having different sensitivities under polarized irradiation. A polarizing layer 400 is arranged between the first photo resist layer 220 and the second photo resist layer 230. The second photo resist layer 230 can be more sensitive than the first photo resist layer 220. A first pattern is exposed in the first photo resist layer 220, using the polarizing layer 400 in between as optical block to reduce exposure of the second photo resist layer 230. The first photo resist layer 220 is exposed in focus with the first pattern and at defocus with the second pattern. The second pattern is exposed in the second photo resist layer 230 with polarized light with focus setting for second photo resist layer 230.

In general, layer thicknesses of the first photo resist layer 220 and the second photo resist layer 230 can be optimized so as to reduce reflectivity into the first photo resist layer 220 for exposure of the second resist layer 230 and to enhance intensity at the surface of the second resist layer 230. The procedure can also be applied for printing of contact or dot arrays by exposure of crossed line and space arrays.

Similar to previous embodiments, no development step is performed after exposure of the first photo resist layer and the substrate remains within the photolithographic projection apparatus 100 between the two exposure steps which greatly reduces overlay errors and errors induced by a substrate holder.

For other applications, a further embodiment is shown with respect to FIGS. 5A to 5C which uses a photosensitive layer stack with two different photo resist layers 220 and 230 having different sensitivity types under irradiation. As shown in FIG. 5A, a photosensitive layer stack is provided including the first photo resist layer 220 and the second photo resist layer 230. The first photo resist layer 220 can be negative and the second photo resist layer 230 can be a positive type resist. Alternatively, the first photo resist layer can be positive and the second photo resist layer can be negative.

As shown in FIG. 5B, the first photo resist layer 220 is exposed by employing a first lithographic projection step. Afterwards developing the photo resist layer 230 is performed, so as to form a first resist structure 610.

As shown in FIG. 5C, the second photo resist layer is exposed by employing a second lithographic projection step. Hereby the already patterned 1^{st} resist may shade the 2^{nd} resist due to absorption of light from the second exposure. Afterwards the second photo resist layer is developed, so as to form a second resist structure 610. If the development is a dry development then the absorption of the 1^{st} resist pattern does not affect the absorption of light from the second exposure. For the second exposure the same mask as for 1^{st} exposure can be used to achieve pitch fragmentation. This reduces overlay errors, e.g., due to the mask registration errors, i.e., placement errors of patterns on the mask.

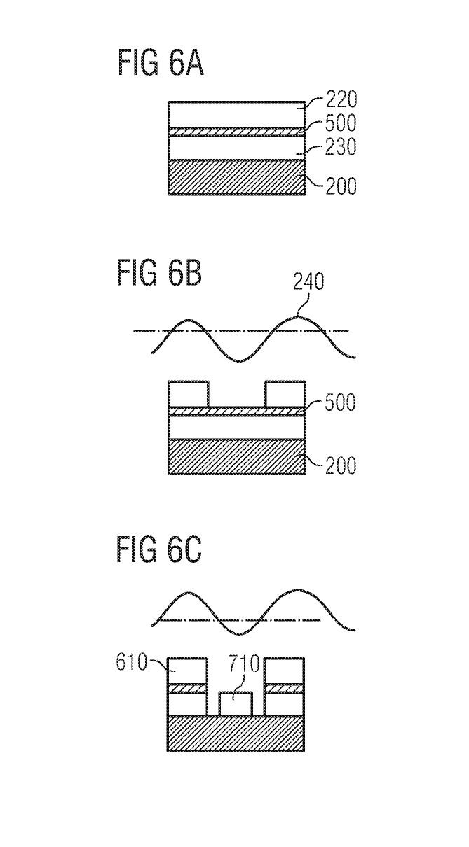

A further implementation is shown with respect to FIGS. 6A to 6C. Again, a photosensitive layer stack with two different photo resist layers 220 and 230 having different sensitivity types under irradiation is used. As shown in FIG. 6A, a photosensitive layer stack is provided including the first photo resist layer 220 and the second photo resist layer 230. Between the first photo resist layer 220 and the second photo resist layer 230 a diffusion layer 500 is arranged which prevents mixing of chemical components, e.g., acids, of the first photo resist layer 220 and the second photo resist layer 230. The first photo resist layer 220 can be negative and the second photo resist layer 230 can be a positive type resist. Alternatively, the first photo resist layer can be positive and the second photo resist layer can be negative.

As shown in FIG. 6B, the first photo resist layer 220 is exposed by employing a first lithographic projection step. Afterwards developing the photo resist layer 230 is performed, so as to form a first resist structure 610.

As shown in FIG. 6C, the second photo resist layer is exposed by employing a second lithographic projection step. Afterwards the second photo resist layer is developed, so as to form a second resist structure 610.

A lithographic system for double patterning includes a lithographic projection apparatus 100. The substrate 110 is arranged on a substrate holder and includes the photosensitive layer stack 210 with two different photosensitive layers 220 and 230. After exposure and processing a pitch fragmentation is achieved. Either the reticle is the same for exposure of both layers or the wafer is not removed from apparatus if two exposures are applied, or both the reticle is the same and the wafer is not removed.

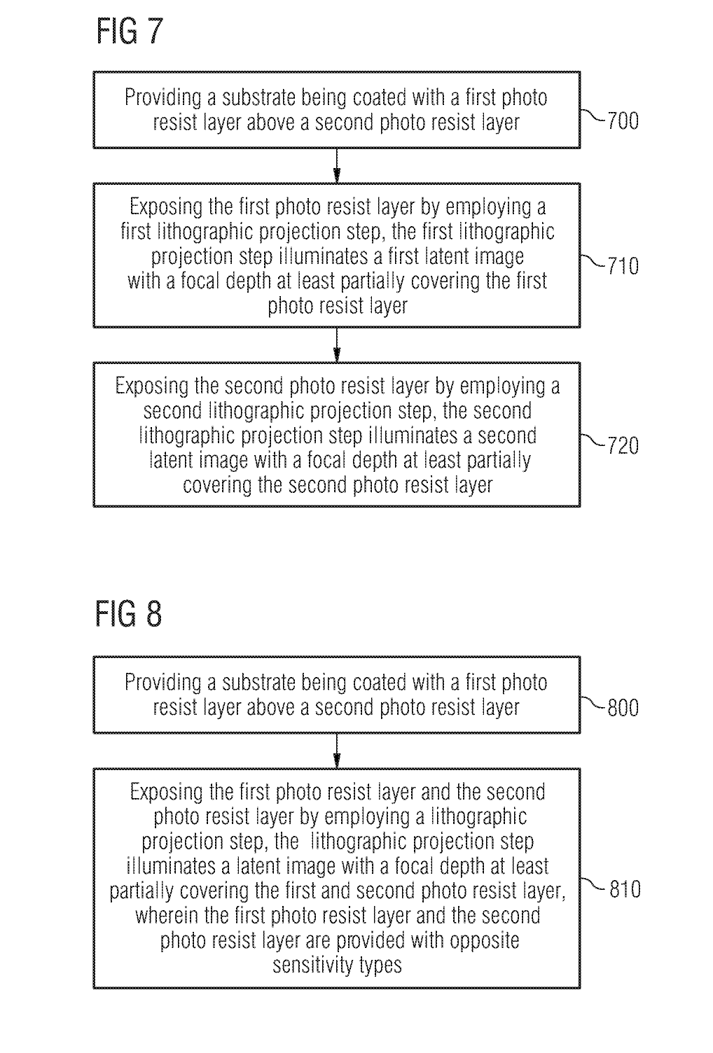

In FIG. 7, a flow diagram is shown with individual process steps capable of double patterning a photo sensitive layer stack.

In step 700, a providing a substrate being coated with a first photo resist layer above a second photo resist layer is performed.

In step 710, exposing the first photo resist layer by employing a first lithographic projection step, the first lithographic projection step illuminates a first latent image with a focal depth at least partially covering the first photo resist layer is performed.

In step 720, exposing the second photo resist layer by employing a second lithographic projection step, the second lithographic projection step illuminates a second latent image with a focal depth at least partially covering the second photo resist layer is performed.

In FIG. 8, a flow diagram is shown with individual process steps capable of double patterning a photo sensitive layer stack.

In step 800, providing a substrate being coated with a first photo resist layer above a second photo resist layer is performed.

In step 810, exposing the first photo resist layer and the second photo resist layer by employing a lithographic projection step, the lithographic projection step illuminates a latent image with a focal depth at least partially covering the first and second photo resist layer, wherein the first photo resist layer and the second photo resist layer are provided with opposite sensitivity types.

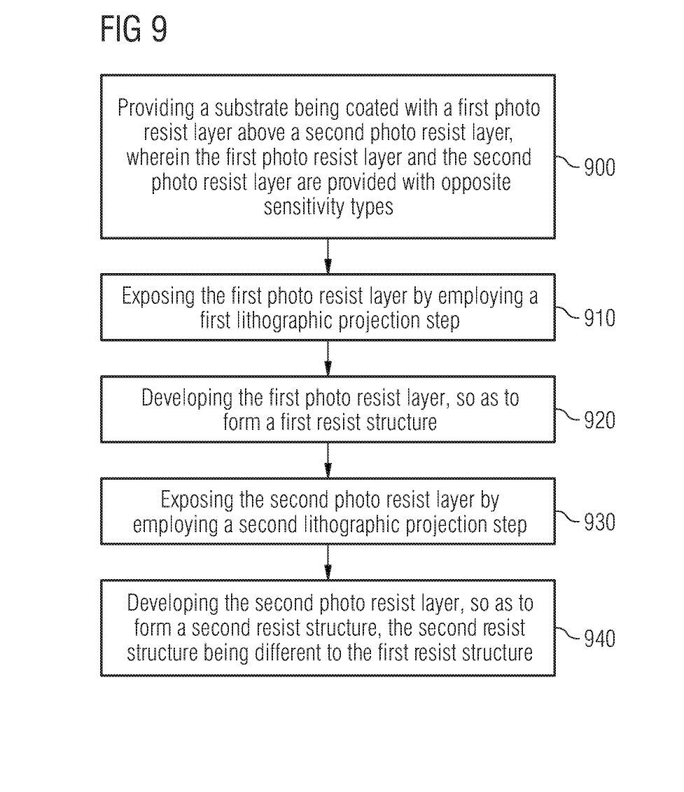

In FIG. 9, a flow diagram is shown with individual process steps capable of double patterning a photo sensitive layer stack.

In step 900, providing a substrate being coated with a first photo resist layer above a second photo resist layer, wherein the first photo resist layer and the second photo resist layer are provided with opposite sensitivity types.

In step 910, exposing the first photo resist layer by employing a first lithographic projection step is performed.

In step 920, developing the first photo resist layer, so as to form a first resist structure is performed.

In step 930, exposing the second photo resist layer by employing a second lithographic projection step is performed.

In step 940, developing the second photo resist layer, so as to form a second resist structure, the second resist structure being different to the first resist structure is performed.

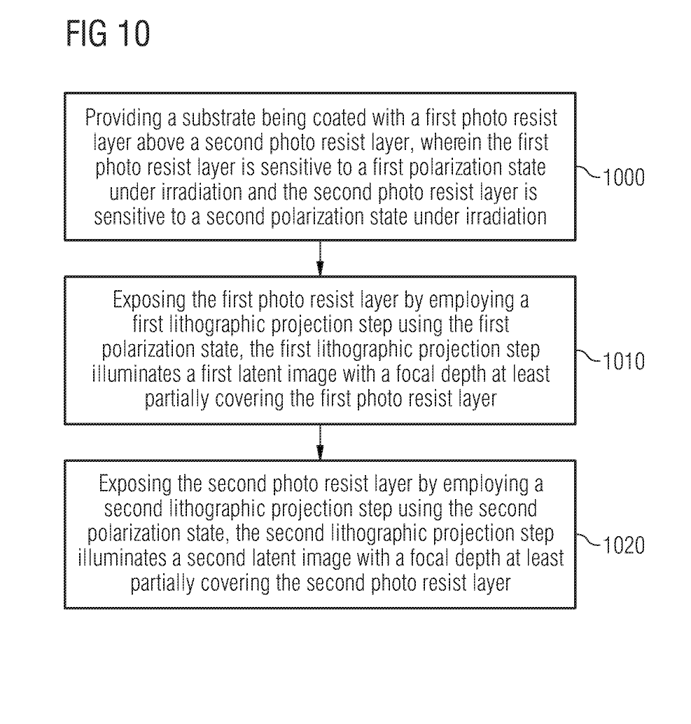

In FIG. 10, a flow diagram is shown with individual process steps capable of double patterning a photo sensitive layer stack.

In step 1000, providing a substrate being coated with a first photo resist layer above a second photo resist layer, wherein the first photo resist layer is sensitive to a first polarization state under irradiation and the second photo resist layer is sensitive to a second polarization state under irradiation is performed.

In step 1010, exposing the first photo resist layer by employing a first lithographic projection step using the first polarization state, the first lithographic projection step illuminates a first latent image with a focal depth at least partially covering the first photo resist layer is performed.

In step 1020, exposing the second photo resist layer by employing a second lithographic projection step using the second polarization state, the second lithographic projection step illuminates a second latent image with a focal depth at least partially covering said second photo resist layer.

Having described embodiments of the invention, it is noted that modifications and variations can be made by persons skilled in the art in light of the above teachings. It is therefore to be understood that changes may be made in the particular embodiments of the invention disclosed which are within the scope and spirit of the invention as defined by the appended claims.

Having thus described the invention with the details and the particularity required by the patent laws, what is claimed and desired to be protected by Letters Patent is set forth in the appended claims. The scope of the invention should, therefore, be determined with reference to the appended claims along with the scope of equivalents to which such claims are entitled.

What is claimed is:

1. A method of double patterning a photo sensitive layer stack, the method comprising:
providing a substrate coated with a first photo resist layer above a second photo resist layer;
exposing the first photo resist layer by employing a first lithographic projection step, wherein the first lithographic projection step illuminates a first latent image with a focal depth at least partially covering the first photo resist layer; and
exposing the second photo resist layer by employing a second lithographic projection step, wherein the second lithographic projection step illuminates a second latent image with a focal depth at least partially covering the second photo resist layer.

2. The method according to claim 1, wherein the first photo resist layer and the second photo resist layer have identical sensitivity types.

3. The method according to claim 1, further comprising a first intermediate layer arranged between the first photo resist layer and the second photo resist layer.

4. The method according to claim 3, wherein the first resist layer is provided as a dry developable top-surface imaging layer.

5. The method according to claim 4, wherein the first photo resist layer is silylated after employing the first lithographic projection step.

6. The method according to claim 5, wherein the first photo resist layer is silylated by a treatment selected from the group consisting of: 1) exposing the first photo resist layer to a liquid, 2) exposing the first photo resist layer to a gas, and 3) providing diffusion from a top coating arranged above the first photo resist layer.

7. The method according to claim 6, wherein the first photo resist layer and the intermediate layer are removed from regions defined by the first latent image by employing a plasma process.

8. The method according to claim 6, wherein the plasma process is performed before the second lithographic step.

9. The method according to claim 3, wherein the first resist layer is provided as a wet developable silicon containing layer.

10. The method according to claim 3, wherein the second resist layer is made etch resistant by diffusion of an agent from the first intermediate layer.

11. The method according to claim 1, wherein a distance between first photo resist layer and the second photo resist layer is selected according to a depth of focus of an optical projection apparatus suitable of performing the first and the second lithographic projection step.

12. The method according to claim 1, wherein the second photo resist layer is removed from regions defined by the second latent image by employing a plasma process.

13. A method of double patterning a photo sensitive layer stack, the method comprising:
providing a substrate coated with a first photo resist layer above a second photo resist layer;
exposing the first photo resist layer and the second photo resist layer by employing a lithographic projection step, wherein the lithographic projection step illuminates a latent image with a focal depth at least partially covering the first and second photo resist layer, wherein the first photo resist layer and the second photo resist layer are provided with opposite sensitivity types.

14. The method according to claim 13, wherein the first photo resist layer is provided as a substantially transparent layer under actinic light.

15. The method according to claim 13, wherein the second photo resist layer is provided with a chemical composition that is different than the first photo resist layer.

16. The method according to claim 15, wherein the first photo resist layer is silylated after exposing the first photo resist layer.

17. The method according to claim 16, wherein the first photo resist layer is silylated by a further treatment being one of: 1) exposing the first photo resist layer to a liquid, 2) exposing the first photo resist layer to a gas, or 3) providing diffusion from a top coating arranged above the first photo resist layer.

18. The method according to claim 13, wherein the second resist layer is made etch resistant by diffusion of an agent from an intermediate layer arranged between the first resist layer and second resist layer.

19. A method of double patterning a photo sensitive layer stack, the method comprising:
providing a substrate coated with a first photo resist layer above a second photo resist layer, wherein the first photo resist layer and the second photo resist layer are provided with opposite sensitivity types;
exposing the first photo resist layer by employing a first lithographic projection step;
developing the first photo resist layer, so as to form a first resist structure;
exposing the second photo resist layer by employing a second lithographic projection step; and
developing the second photo resist layer, so as to form a second resist structure, the second resist structure being different from the first resist structure.

20. The method according to claim 19, further comprising transferring the first resist structure and the second resist structure in a layer arranged between the substrate and the second photo resist layer.

21. The method according to claim 19, further comprising providing a diffusion layer between the first resist layer and the second resist layer.

22. A method of double patterning a photo sensitive layer stack, the method comprising:
providing a substrate coated with a first photo resist layer above a second photo resist layer, wherein the first photo resist layer is sensitive to a first polarization state under irradiation and the second photo resist layer is sensitive to a second polarization state under irradiation;
exposing the first photo resist layer by employing a first lithographic projection step using the first polarization state, the first lithographic projection step illuminates a first latent image with a focal depth at least partially covering the first photo resist layer; and
exposing the second photo resist layer by employing a second lithographic projection step using the second polarization state, the second lithographic projection step illuminates a second latent image with a focal depth at least partially covering the second photo resist layer.

23. The method according to claim 22, further comprising providing a polarizing layer between the first resist layer and the second resist layer.

24. A photosensitive layer stack, comprising two photo resist layers, the photosensitive layer stack being capable of performing double patterning by employing two subsequent exposures followed by a developer step.

25. A lithographic system, comprising:
a lithographic projection apparatus including a substrate holder and a photo mask;
a substrate being arranged on the substrate holder, the substrate including photosensitive layer stack, comprising two photo resist layers being capable of performing double patterning by employing two subsequent exposures followed by a developer step, wherein a distance between a first photo resist layer and a second photo resist layer is selected according to a depth of focus of the lithographic projection apparatus suitable of performing the first and the second lithographic projection step.
